(19) United States
(12) Patent Application Publication
(10) Pub. No.: US 2026/0215084 A1
(43) Pub. Date: Jul. 23, 2026

(54) LIGHT-EMITTING DEVICE AND ELECTRONIC APPARATUS INCLUDING THE SAME

(71) Applicants: Samsung Display Co., Ltd., Yongin-si (KR); Seoul National University R&DB Foundation, Seoul (KR)

(72) Inventors: Myoungjin Park, Yongin-si (KR); Jeonghun Kwak, Seoul (KR); Kwangkeun Lee, Yongin-si (KR)

(21) Appl. No.: 19/457,247

(22) Filed: Jan. 23, 2026

(30) Foreign Application Priority Data
Jan. 23, 2025 (KR) 10-2025-0010662

(51) Int. Cl. H10K 50/16; H10K 50/115

(52) U.S. Cl. CPC H10K 50/166; H10K 50/115

(57) ABSTRACT

A light-emitting device includes a first electrode, a second electrode facing the first electrode, and an interlayer arranged between the first electrode and the second electrode and including an emission layer. The emission layer includes a quantum dot. A charge modulation layer is arranged between the first electrode and the emission layer.

### CROSS-REFERENCE TO RELATED APPLICATIONS

This application claims priority under 35 U.S.C. § 119 to Korean Patent Application No. 10-2025-0010662, filed on Jan. 23, 2025 in the Korean Intellectual Property Office, the disclosure of which is incorporated by reference in its entirety herein.

### 1. TECHNICAL FIELD

One or more embodiments relate to a light-emitting device and an electronic apparatus including the light-emitting device.

### 2. DISCUSSION OF RELATED ART

Quantum dots are nanocrystals of semiconductor materials which exhibit a quantum confinement effect. When quantum dots receive light from an excitation source and reach an energy excited state, the quantum dots release energy by themselves according to a corresponding energy band gap. In this regard, even in the same material, the wavelength varies according to the particle size, and accordingly, by adjusting the size of quantum dots, light of a desired wavelength range may be obtained, and excellent color purity and high luminescence efficiency may be obtained. Thus, the quantum dots may be applicable to various devices.

In addition, a quantum dot can be used as a material that performs various optical functions, such as a photo-conversion function, in optical members. Quantum dots, as nano-sized semiconductor nanocrystals, may have different energy band gaps by adjusting the size and composition of the nanocrystals, and thus may emit light of various emission wavelengths.

An optical member including such quantum dots may be in the form of a thin film, for example, a thin film patterned for each subpixel. Such an optical member may be used as a color conversion member of a device including various light sources.

When there is an unbalance in a charge injection from a hole injection layer and/or a hole transport layer to a quantum dot emission layer, a deterioration of a hole injection layer composed of an organic material and/or a hole transport layer composed of an organic material occurs and a pixel lifespan decreases due to the deterioration. A lifespan of a light-emitting device with the pixel also decreases. Therefore, research is being conducted to increase the lifespan of the pixel and the light-emitting device which includes quantum dots.

### SUMMARY

One or more embodiments include a light-emitting device and an electronic apparatus including the same, the light-emitting device having a simple structure without a hole injection layer and a hole transport layer and having no deterioration problem.

Additional aspects will be set forth in part in the description which follows and, in part, will be apparent from the description, or may be learned by practice of the described embodiments of the disclosure.

According to one or more embodiments of the present disclosure, a light-emitting device includes a first electrode, a second electrode facing the first electrode, and an interlayer arranged between the first electrode and the second electrode and including an emission layer. The emission layer includes a quantum dot. A charge modulation layer is arranged between the first electrode and the emission layer.

In an embodiment, the first electrode may be an anode, the second electrode may be a cathode, and the interlayer may further include an electron transport region include a hole blocking layer, an electron transport layer, an electron injection layer, or any combination thereof.

In an embodiment, the electron transport region may be arranged between the second electrode and the emission layer, and may include the electron transport layer and/or the electron injection layer. The electron transport layer and/or the electron injection layer may each independently include an inorganic compound, an organic compound or any combination thereof.

In an embodiment, the electron transport layer and the electron injection layer may each independently include ZnMgOₓ, ZnOₓ, Cs₂CO₃, TiOₓ, WOₓ, SnOₓ, ZnS, 4,7-diphenyl-1,10-phenanthroline (BPhen), 2,2′,2″-(1,3,5-benzinetriyl)-tris(1-phenyl-1-H-benzimidazole) (TPBi), Alq₃, 2,9-dimethyl-4,7-diphenyl-1,10-phenanthroline (BCP), or any combination thereof. Each x may independently represent a number in a range of about 0.1 to about 3.

In an embodiment, the charge modulation layer may include an inorganic insulating material, an organic insulating material, or any combination thereof.

In an embodiment, the inorganic insulating material may include an aluminum oxide, an aluminum nitride, a titanium nitride, an alkali metal halide, a silicon oxide, a silicon nitride, a silicon oxynitride, a hafnium oxide, a zirconium oxide, or an oxide of a combination of two or more of aluminum, silicon, hafnium, and zirconium.

In an embodiment, the inorganic insulating material may include Al₂O₃, SiOₓ, SiNₓ, SiOₓN_{y}, HfO₂, ZrO₂, HfSiO₄, HfAlO, AlNₓ, TiNₓ, LiF, or any combination thereof. Each x may independently represent a number in a range of about 0.1 to about 3, and y may independently represent a number in a range of about 0.1 to about 3.

In an embodiment, the organic insulating material may include poly(methyl methacrylate) (PMMA), polyvinyl alcohol (PVA), or any combination thereof.

In an embodiment, the first electrode may be an anode, the second electrode may be a cathode, and a thickness of the charge modulation layer may be less than or equal to about 5 nm.

In an embodiment, the first electrode and/or the second electrode may be a transmissive electrode.

In an embodiment, the transmissive electrode may have a single-layer structure or a multilayer structure, each including a metal oxide or a metal.

In an embodiment, the metal oxide may include an indium tin oxide (ITO), an indium zinc oxide (IZO), a tin oxide doped with a fluorine (FTO), a molybdenum oxide (MoOₓ), a vanadium oxide (VOₓ), a nickel oxide (NiOₓ), a tin oxide (SnO₂), a zinc oxide (ZnO), or any combination thereof. Each x may independently represent a number in a range of about 0.1 to about 3.

In an embodiment, the metal may include a magnesium (Mg), a silver (Ag), a gold (Au), an aluminum (Al), an aluminum-lithium (Al—Li), a calcium (Ca), a magnesium-indium (Mg—In), a magnesium-silver (Mg—Ag), or any combination thereof.

In an embodiment, the quantum dot may have a core-shell structure. The core-shell structure includes a core including a semiconductor compound, and a shell including an oxide of a metal, a metalloid, or a non-metal, a semiconductor compound, or a combination thereof.

In an embodiment, the semiconductor compound may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or a combination thereof, and the oxide of a metal, a metalloid, or a non-metal may each independently include SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, or a combination thereof.

In an embodiment, the semiconductor compound may include CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, InAlZnP, GaS, GaSe, Ga₂Se₃, GaTe, InS, InSe, In₂S₃, In₂Se₃, InTe, InGaS₃, InGaSe₃, AgInS, AgInS₂, CuInS, CuInS₂, CuGaO₂, AgGaO₂, AgAlO₂, AgInGaS, AgInGaS₂, CuInGaS₂, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, SiGe or any combination thereof.

In an embodiment, the semiconductor compound included in the shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or any combination thereof.

According to an embodiment of the present disclosure, an electronic apparatus includes a processor. A memory has stored application programs for execution by the processor. A light-emitting device includes a first electrode. A second electrode facing the first electrode. An interlayer arranged directly between the first electrode and the second electrode and comprising an emission layer. The interlayer does not include any of a hole injection layer and a hole transport layer. The emission layer comprises a quantum dot. A charge modulation layer is arranged between the first electrode and the emission layer.

In an embodiment, the light-emitting device may include a display module. The electronic apparatus may include a power module including a power supply module supplying power to the electronic apparatus.

In an embodiment, the electronic apparatus may be one of a smartphone, a tablet PC, a laptop, a TV, a desk monitor, smart glasses, a head mounted display, a smart watch, an automobile instrument panel, a center fascia, a center information display (CID) arranged on a dashboard of an automobile (e.g., an automobile instrument panel), and a room mirror display.

### BRIEF DESCRIPTION OF THE DRAWINGS

The above and other aspects, features, and advantages of certain non-limiting embodiments of the present disclosure will be more apparent from the following description taken in conjunction with the accompanying drawings, in which:

FIG. 1 is a schematic view of a structure of a light-emitting device according to an embodiment,

FIG. 2 is a cross-sectional view of an electronic apparatus according to an embodiment.

FIG. 3 is a cross-sectional view of an electronic apparatus according to another embodiment of the present disclosure.

FIG. 4 shows a block diagram of an electronic device according to an embodiment; and

FIG. 5 shows schematic diagrams of an electronic device according to various embodiments.

### DETAILED DESCRIPTION OF EMBODIMENTS

Reference will now be made in detail to embodiments, examples of which are illustrated in the accompanying drawings, wherein like reference numerals refer to like elements throughout. In this regard, embodiments of the present disclosure may have different forms the described embodiments and should not be construed as being limited to the descriptions set forth herein. Accordingly, non-limiting embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since the disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the described embodiments set forth herein.

An expression used in the singular encompasses the expression of the plural, unless it has a clearly different meaning in the context.

It will be further understood that the terms “comprises” and/or “comprising” used herein specify the presence of stated features or elements, but do not preclude the presence or addition of one or more other features or elements.

It will be understood that when a layer, region, or component is referred to as being “on” or “onto” another layer, region, or component, it may be directly or indirectly formed on the other layer, region, or component. That is, for example, intervening layers, regions, or components may be present. When a layer, region, or component is referred to as being “directly on” or “directly onto” another layer, region, or component, no intervening elements may be present.

In descriptions with reference to the drawings, identical or corresponding elements are assigned identical or like reference numerals, and overlapping descriptions thereof will be omitted.

Sizes of elements in the drawings may be exaggerated for convenience of explanation. In other words, since sizes and thicknesses of components in the drawings may be arbitrarily illustrated for convenience of explanation, the following embodiments are not necessarily limited thereto.

The present disclosure concerns a light-emitting device that includes an interlayer disposed between a first electrode and a second electrode. The interlayer includes a charge modulation layer arranged between the first electrode and the emission layer of the interlayer. The interlayer does not include a hole injection layer, a hole transport layer, an emission auxiliary layer or an electron blocking layer. Therefore, the light-emitting device may avoid the deterioration of the organic material that is typically included in these omitted layers and the light-emitting device may have an increased lifespan and luminescence efficiency.

A light-emitting device according to one aspect may include:
a first electrode;
a second electrode facing the first electrode; and
an interlayer between the first electrode and the second electrode and including an emission layer,
wherein the emission layer may include a quantum dot and,
a charge modulation layer may be arranged between the first electrode and the emission layer.

According to one or more embodiments, the light-emitting device may not include a hole injection layer and a hole transport layer. Therefore, there is no life span decrease due to a deterioration of a hole injection layer or a hole transport layer composed of organic material. According to one or more embodiments, the light-emitting device not including a hole injection layer and hole transport layer may be a quantum dot light-emitting device of Schottky diode structure.

According to one or more embodiments, the charge modulation layer may be a layer including an insulating material. For example, the charge modulation layer may be a layer consisting of an insulating material.

According to one or more embodiments, the first electrode may be an anode, the second electrode may be a cathode, and the interlayer further may include an electron transport region comprising a hole blocking layer, an electron transport layer, an electron injection layer, or any combination thereof.

According to one or more embodiments, the electron transport region may be arranged between the second electrode and the emission layer, and may include the electron transport layer and/or the electron injection layer,
wherein the electron transport layer and/or the electron injection layer may each independently include an inorganic compound, an organic compound or any combination thereof.

According to one or more embodiments, the electron transport layer may be arranged between the second electrode and the emission layer and the electron transport layer may include an inorganic compound. For example, the electron transport layer may consist of an inorganic compound.

According to one or more embodiments, the electron transport layer and the electron injection layer may each independently include ZnMgOₓ, ZnOₓ, Cs₂CO₃, TiOₓ, WOₓ, SnOₓ, ZnS, BPhen (4,7-Diphenyl-1,10-phenanthroline), TPBi (2,2′,2″-(1,3,5-Benzinetriyl)-tris(1-phenyl-1-H-benzimidazole), Alq₃, BCP (2,9-Dimethyl-4,7-diphenyl-1,10-phenanthroline), or any combination thereof. Wherein, each x may independently represent a number of about 0.1 to about 3. For example, each x may independently represent a number of about 0.5 to about 3.0. For example, each x may independently represent a number of about 0.7 to about 2.5.

According to one or more embodiments, the charge modulation layer may include an inorganic insulating material, an organic insulating material, or any combination thereof.

For example, the charge modulation layer may consist of an inorganic insulating material, an organic insulating material, or any combination thereof.

According to one or more embodiments, the inorganic insulating material of the charge modulation layer may include an aluminum oxide; an aluminum nitride; a titanium nitride; an alkali metal halide; a silicon oxide; a silicon nitride; a silicon oxynitride; a hafnium oxide; a zirconium oxide; or an oxide of a combination of 2 or more of an aluminum, a silicon, a hafnium and a zirconium.

According to one or more embodiments, the inorganic insulating material may include Al₂O₃, SiOₓ, SiNₓ, SiOₓN_{y}, HfO₂, ZrO₂, HfSiO₄, HfAlO, AlNₓ, TiNₓ, LiF, or any combination thereof.

Wherein, each x may independently represent a number of about 0.1 to about 3 and y may represent a number of about 0.1 to about 3. For example, each x may independently represent a number of about 0.5~about 3.0 and y may represent a number of about 0.5 to about 3.0. For example, each x may independently represent a number of about 0.7 to about 2.5 and y may represent a number of about 0.7 to about 2.5.

According to one or more embodiments, the organic insulating material may include PMMA (Poly(methyl methacrylate)), PVA (polyvinyl alcohol), or any combination thereof.

According to one or more embodiments, the layer may consist of an insulating material. The layer consists of an insulating material, so electric current does not flow in normal condition. The layer may block exciton quenching occurring from contact of an emission layer and an electrode.

According to one or more embodiments, the first electrode may be an anode, the second electrode may be a cathode, and a thickness of the charge modulation layer may be in a range of more than about 0 nm to about 5 nm. Tunneling of a hole may be possible in the range of the thickness. When the thickness exceeds 5 nm, the driving voltage may increase.

According to one or more embodiments, the first electrode and/or the second electrode may be a transmissive electrode. According to one or more embodiments, the light-emitting device may be a top emission light-emitting device or a bottom emission light-emitting device.

According to one or more embodiments, the transmissive electrode may have a single-layer structure or a multilayer structure each including a metal oxide or a metal.

According to one or more embodiments, the metal oxide may include an indium tin oxide (ITO), an indium zinc oxide (IZO), a tin oxide doped with a fluorine (FTO), a molybdenum oxide (MoOₓ), a vanadium oxide (VOₓ), a nickel oxide (NiOₓ), a tin oxide (SnO₂), a zinc oxide (ZnO), or any combination thereof, wherein, each x may independently represent a number of about 0.1 to about 3. For example, each x may independently represent a number of about 0.5 to about 3.0. For example, each x may independently represent a number of about 0.7 to about 2.5.

According to one or more embodiments, the metal may include a magnesium (Mg), a silver (Ag), a gold (Au), an aluminum (Al), an aluminum-lithium (Al—Li), a calcium (Ca), a magnesium-indium (Mg—In), a magnesium-silver (Mg—Ag), or any combination thereof.

For example, the transmissive electrode may have a structure of a first transmissive electrode/a transflective electrode/a second transmissive electrode. In this case, an efficiency of the light-emitting device may be increased due to the resonance effect. For example, the transmissive electrode may have a structure of ITO (45 nm)/Ag (25 nm)/ITO (65 nm) based on an emission wavelength of a red quantum dot. In this case, compared to an light-emitting device including a ITO single-layer structure, the luminous efficiency of an light-emitting device including the transmissive electrode may increase about 60% and the optical extraction efficiency of the light-emitting device may increase about 25% to 40%. In the above structure, the ITO (65 nm) layer may be in direct contact with the charge modulation layer.

The quantum dot may be described later.

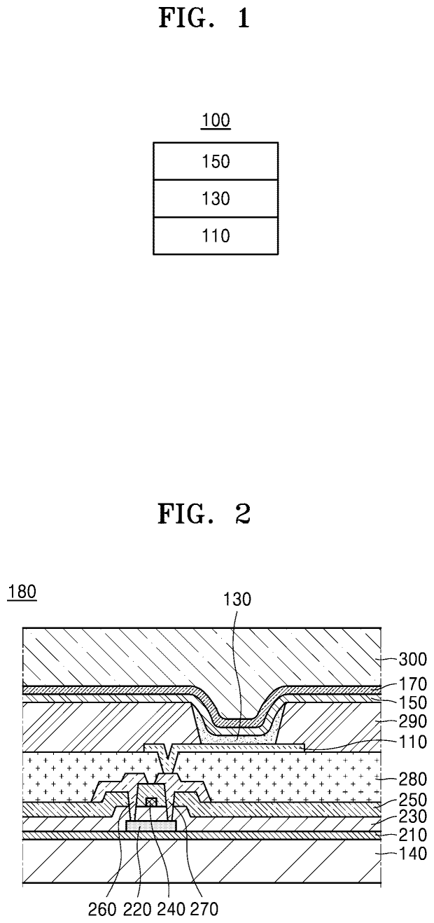

### [Description of FIG. 1]

FIG. 1 is a schematic cross-sectional view of a light-emitting device 100 according to an embodiment. In an embodiment, the light-emitting device 100 includes a first electrode 110, an interlayer 130, and a second electrode 150.

Hereinafter, the structure of the light-emitting device 100 according to an embodiment and a method of manufacturing the light-emitting device 100 will be described in connection with FIG. 1.

### [First Electrode 110]

In FIG. 1, a substrate may be additionally located under the first electrode 110 or on the second electrode 150 (e.g., above the second electrode). In an embodiment, as the substrate, a glass substrate or a plastic substrate may be used. According to one or more embodiments, the substrate may be a flexible substrate and may include plastics with excellent heat resistance and durability, such as polyimide, polyethylene terephthalate (PET), polycarbonate, polyethylene naphthalate, polyarylate (PAR), polyetherimide, or any combination thereof.

In an embodiment, the first electrode 110 may be formed by, for example, depositing or sputtering a material for forming the first electrode 110 on the substrate. In an embodiment in which the first electrode 110 is an anode, a material for forming the first electrode 110 may be a high-work function material that facilitates injection of holes.

The first electrode 110 may be a reflective electrode, a transreflective electrode, or a transmissive electrode. In an embodiment, as the first electrode material, an indium tin oxide (ITO), an indium zinc oxide (IZO), a tin oxide doped with a fluorine (FTO), a molybdenum oxide (MoOₓ), a vanadium oxide (VOₓ), a nickel oxide (NiOₓ), a tin oxide (SnO₂), a zinc oxide (ZnO), or any combination thereof may be used to form the first electrode 110 of a transmissive electrode. in which each x may independently represent a number in a range of about 0.1 to about 3. According to one or more embodiments, when the first electrode 110 is a transflective electrode or a reflective electrode, a magnesium (Mg), a silver (Ag), an aluminum (Al), an aluminum-lithium (Al—Li), a calcium (Ca), a magnesium-indium (Mg—In), a magnesium-silver (Mg—Ag), or any combination thereof as a material for forming the first electrode 110 may be used.

The first electrode 110 may have a single-layered structure consisting of a single layer or a multi-layered structure including a plurality of layers. According to one or more embodiments, the first electrode 110 may have a three-layer structure of ITO/Ag/ITO.

### [Interlayer 130]

The interlayer 130 may be located on the first electrode 110 (e.g., disposed directly thereabove). The interlayer 130 may include an emission layer.

In an embodiment, the interlayer 130 may include the charge modulation layer arranged between the first electrode 110 and the emission layer. The charge modulation layer may include an inorganic insulating material, an organic insulating material, or any combination thereof. For example, in an embodiment the inorganic insulating material of the charge modulation layer may comprise an aluminum oxide; an aluminum nitride; a titanium nitride; an alkali metal halide; a silicon oxide; a silicon nitride; a silicon oxynitride; a hafnium oxide; a zirconium oxide; or an oxide of a combination of 2 or more of an aluminum, a silicon, a hafnium and a zirconium. For example, in an embodiment the inorganic insulating material of the charge modulation layer may comprise Al₂O₃, SiOₓ, SiNₓ, SiOₓN_{y}, HfO₂, ZrO₂, HfSiO₄, HfAlO, AlNₓ, TiNₓ, LiF, or any combination thereof in which x is a number in a range of about 0.1 to about 3, and y is a number in a range of about 0.1 to about 3. In an embodiment, the organic insulating material of the charge modulation layer comprises poly(methyl methacrylate) (PMMA), polyvinyl alcohol (PVA), or any combination thereof. In an embodiment, a thickness (e.g., a total thickness) of the charge modulation layer may be less than or equal to about 5 nm.

The interlayer 130 may not include a hole injection layer, a hole transport layer, an emission auxiliary layer or an electron blocking layer.

The interlayer 130 may further include an electron transport region arranged between the emission layer and the second electrode 150.

In an embodiment, the interlayer 130 may further include, in addition to various organic materials, a metal-containing compound such as an organometallic compound, an inorganic material such as quantum dots, or the like.

According to one or more embodiments, the interlayer 130 may include, i) two or more emitting units sequentially stacked between the first electrode 110 and the second electrode 150, and ii) a charge generation layer between adjacent emitting units among the two or more emitting units. In an embodiment in which the interlayer 130 includes the emitting units and the charge generation layer as described above, the light-emitting device 100 may be a tandem light-emitting device.

### [Emission Layer in Interlayer 130]

In an embodiment in which the light-emitting device 100 is a full-color light-emitting device, the emission layer may be patterned into a red emission layer, a green emission layer, and/or a blue emission layer, according to a subpixel. According to one or more embodiments, the emission layer may have a stacked structure of two or more layers of a red emission layer, a green emission layer, and a blue emission layer, in which the two or more layers directly contact each other or are separated from each other, to emit white light. In one or more embodiments, the emission layer may include two or more materials of a red light-emitting material, a green light-emitting material, and a blue light-emitting material, in which the two or more materials are mixed with each other in a single layer, to emit white light.

In an embodiment, a thickness of the emission layer may be in a range of about 100 Å to about 1,000 Å, for example, about 200 Å to about 600 Å. In an embodiment in which the thickness of the emission layer is within these ranges, excellent light-emission characteristics may be obtained without a substantial increase in driving voltage.

### [Quantum Dot]

The emission layer may include a quantum dot.

The term “quantum dot” as used herein refers to a crystal of a semiconductor compound, and may include any material capable of emitting light of various emission wavelengths according to the size of the crystal. Quantum dots may emit light of various emission wavelengths by adjusting the element ratio in the quantum dot compound.

In an embodiment, a diameter of the quantum dot may be, for example, in a range of about 1 nm to about 10 nm.

In an embodiment, the quantum dot may be synthesized by a wet chemical process, a metal organic chemical vapor deposition process, a molecular beam epitaxy process, or any process similar thereto.

The wet chemical process is a method including mixing a precursor material with an organic solvent and then growing a quantum dot particle crystal. When the crystal grows, the organic solvent naturally acts as a dispersant coordinated on the surface of the quantum dot crystal and controls the growth of the crystal so that the growth of quantum dot particles can be controlled through a process which costs lower, and is easier than vapor deposition methods, such as metal organic chemical vapor deposition (MOCVD) or molecular beam epitaxy (MBE),

In an embodiment, the quantum dot may include Group II-VI semiconductor compounds, Group III-V semiconductor compounds, Group III-VI semiconductor compounds, Group I-III-VI semiconductor compounds, Group IV-VI semiconductor compounds, a Group IV element or compound, or any combination thereof. These materials may be included in the core and/or the shell of the quantum dot.

In an embodiment, examples of the Group II-VI semiconductor compound are a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or any combination thereof.

In an embodiment, examples of the Group III-V semiconductor compound may include: a binary compound, such as GaN, GaP, GaAs, GaSb, AlN, AlP, AlAs, AlSb, InN, InP, InAs, or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or any combination thereof. In some embodiments, the Group III-V semiconductor compound may further include a Group II element. Examples of the Group III-V semiconductor compound further including a Group II element are InZnP, InGaZnP, InAlZnP, etc.

In an embodiment, examples of the Group III-VI semiconductor compound are: a binary compound, such as GaS, GaSe, Ga₂Se₃, GaTe, InS, InSe, In₂S₃, In₂Se₃, or InTe; a ternary compound, such as InGaS₃, or InGaSe₃; and any combination thereof.

In an embodiment, examples of the Group I-III-VI semiconductor compounds include ternary compounds such as AgInS, AgInS₂, CuInS, CuInS₂, CuGaO₂, AgGaO₂, AgAlO₂, etc.; or a combination such as AgInGaS, AgInGaS₂, CuInGaS₂.

In an embodiment, examples of the Group IV-VI semiconductor compound are: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, or SnPbTe; a quaternary compound, such as SnPbSSe, SnPbSeTe, or SnPbSTe; or any combination thereof.

In an embodiment, the Group IV element or compound may include: a single element compound, such as Si or Ge; a binary compound, such as SiC or SiGe; or any combination thereof.

In an embodiment, each element included in a multi-element compound such as the binary compound, the ternary compound, and the quaternary compound may be present at a uniform concentration or non-uniform concentration in a particle.

The quantum dot may have a single structure in which the concentration of each element in the quantum dot is uniform, or a core-shell dual structure. For example, the material included in the core and the material included in the shell may be different from each other.

The shell of the quantum dot may act as a protective layer that prevents chemical degeneration of the core to maintain semiconductor characteristics, and/or as a charging layer that imparts electrophoretic characteristics to the quantum dot. The shell may be a single layer or a multi-layer. In an embodiment, the interface between the core and the shell may have a concentration gradient in which the concentration of an element existing in the shell decreases towards the center of the core.

In an embodiment, examples of the shell of the quantum dot may be an oxide of metal, metalloid, or non-metal, a semiconductor compound, and any combination thereof. Examples of the oxide of metal, metalloid, or non-metal are a binary compound, such as SiO₂, Al₂O₃, TiO₂, ZnO, MnO, Mn₂O₃, Mn₃O₄, CuO, FeO, Fe₂O₃, Fe₃O₄, CoO, CO₃O₄, or NiO; a ternary compound, such as MgAl₂O₄, CoFe₂O₄, NiFe₂O₄, or CoMn₂O₄; and any combination thereof. Examples of the semiconductor compound are, as described herein, a Group II-VI semiconductor compound; a Group III-V semiconductor compound; a Group III-VI semiconductor compound; a Group I-III-VI semiconductor compound; a Group IV-VI semiconductor compound; and any combination thereof. For example, in an embodiment the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof. For example, in an embodiment the quantum dot may have a core-shell structure in which the core comprises a semiconductor compound and the shell comprises an oxide of a metal, a metalloid, a non-metal, a semiconductor compound, or a combination thereof.

In an embodiment, a full width at half maximum (FWHM) of the emission wavelength spectrum of the quantum dot may be in a range of less than or equal to about 45 nm, for example, less than or equal to about 40 nm, for example, less than or equal to about 30 nm, and within these ranges, color purity or color reproducibility may be increased. In addition, since the light emitted through the quantum dot is emitted in all directions, the wide viewing angle may be increased.

In addition, in some embodiments the quantum dot may be in the form of a spherical particle, a pyramidal particle, a multi-arm particle, a cubic nanoparticle, a nanotube particle, a nanowire particle, a nanofiber particle, or a nanoplate particle.

Since the energy band gap may be adjusted by controlling the size of the quantum dot, light having various wavelength bands may be obtained from the quantum dot emission layer. Accordingly, by using quantum dots of different sizes, a light-emitting device that emits light of various wavelengths may be implemented. In one or more embodiments, the size of the quantum dot may be selected to emit red, green and/or blue light. In addition, the size of the quantum dot may be configured to emit white light by combination of light of various colors.

### [Electron Transport Region in Interlayer 130]

The electron transport region may have: i) a single-layered structure consisting of a single layer consisting of a single material, ii) a single-layered structure consisting of a single layer consisting of a plurality of different materials, or iii) a multi-layered structure including a plurality of layers including different materials from each other.

In an embodiment, the electron transport region may include a hole-blocking layer, an electron transport layer, an electron injection layer, or any combination thereof.

In an embodiment, the electron transport region may have an electron transport layer/electron injection layer structure or a hole-blocking layer/electron transport layer/electron injection layer structure, in which in each structure, constituting layers are sequentially stacked from the emission layer.

In an embodiment, the electron transport region (e.g., the hole-blocking layer, or the electron transport layer in the electron transport region) may include a metal-free compound including at least one π electron-deficient nitrogen-containing C₁-C₆₀ cyclic group.

According to one or more embodiments, the electron transport region may include a compound represented by Formula 601.

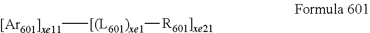

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described herein with respect to Q₁, xe21 may be 1, 2, 3, 4, or 5,
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

According to one or more embodiments, when xe11 in Formula 601 is 2 or more, two or more of Ar₆₀₁ may be linked together via a single bond.

According to one or more embodiments, Ar₆₀₁ in Formula 601 may be a substituted or unsubstituted anthracene group.

According to one or more embodiments, the electron transport region may include a compound represented by Formula 601-1:

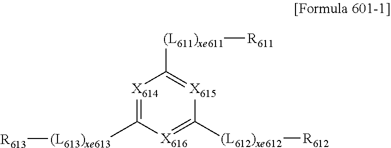

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ may each be the same as described herein with respect to L₆₀₁, xe611 to xe613 may each be the same as described herein with respect to xe1,
R₆₁₁ to R₆₁₃ may each be the same as described herein with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

According to one or more embodiments, xe1 and xe611 to xe613 in Formulae 601 and 601-1 may each independently be 0, 1, or 2.

In an embodiment, the electron transport region may include one of Compounds ET1 to ET45, 2,9-dimethyl-4,7-diphenyl-1,10-phenanthroline (BCP), 2,2′,2″-(1,3,5-Benzinetriyl)-tris(1-phenyl-1-H-benzimidazole) (TPBi), 4,7-diphenyl-1,10-phenanthroline (Bphen), Alq₃, BAlq, TAZ, NTAZ, or any combination thereof:

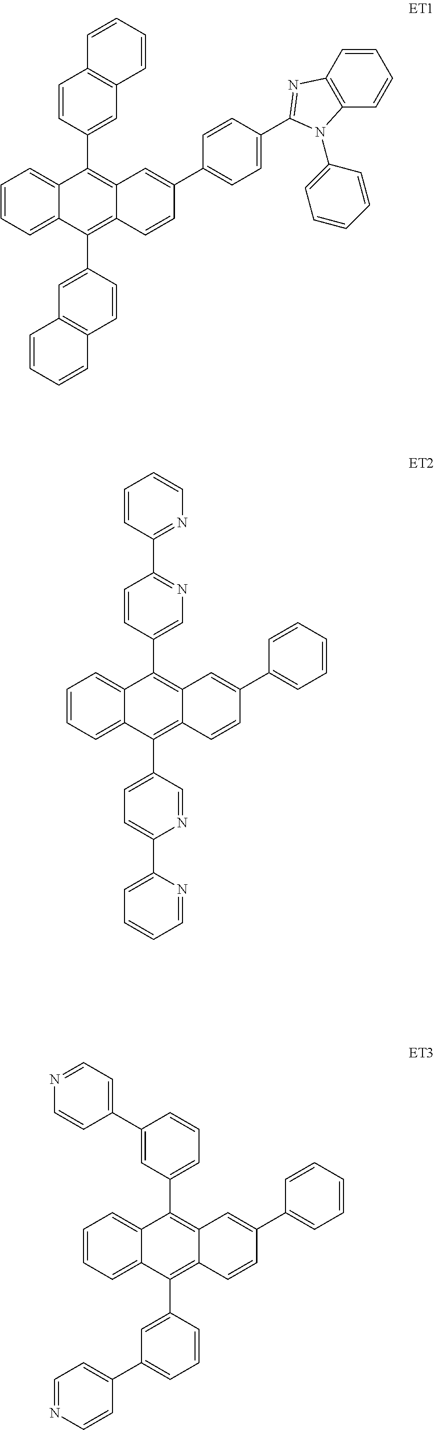 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

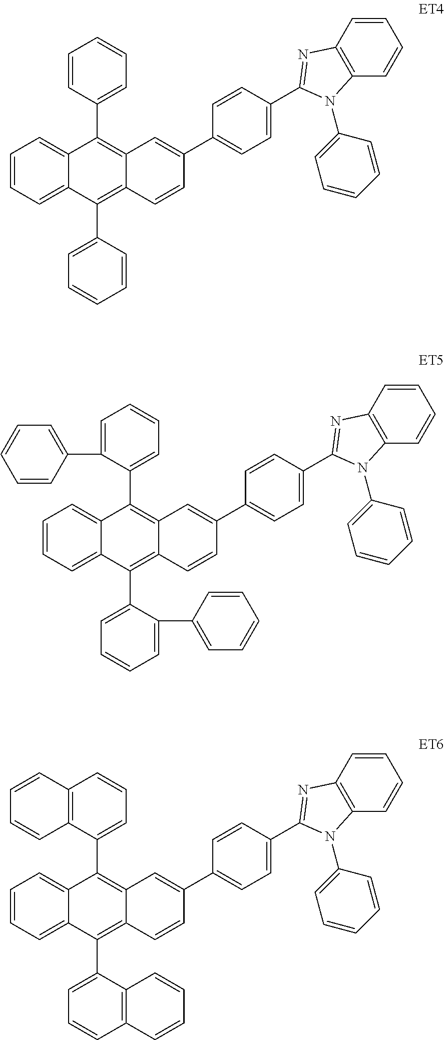 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

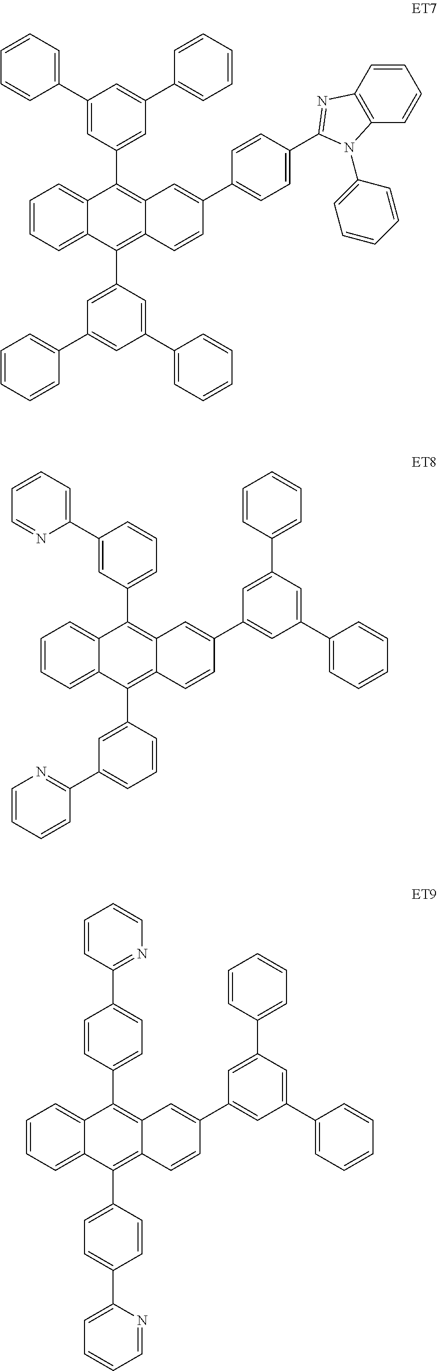 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

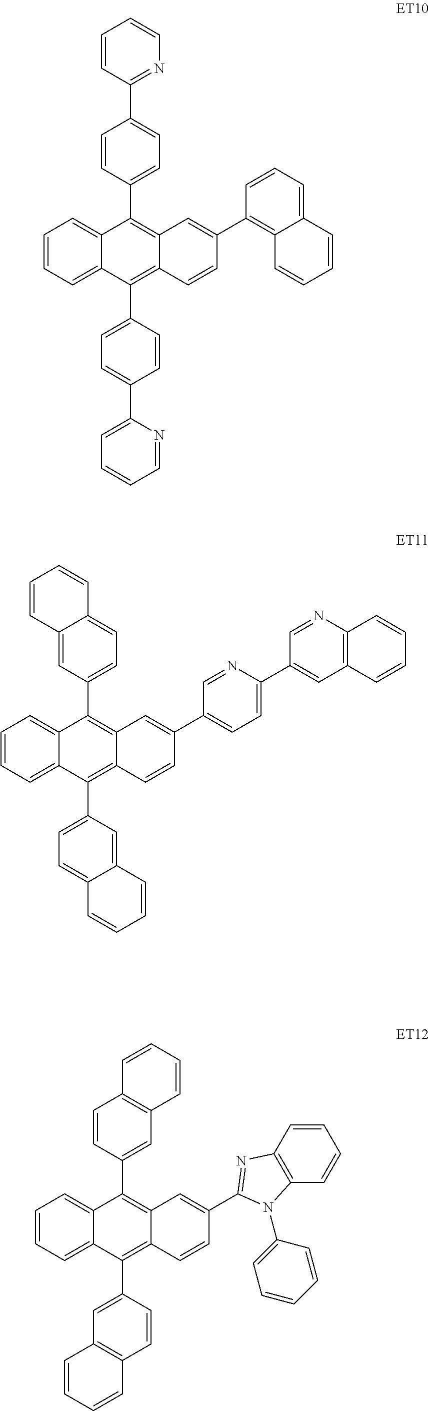 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

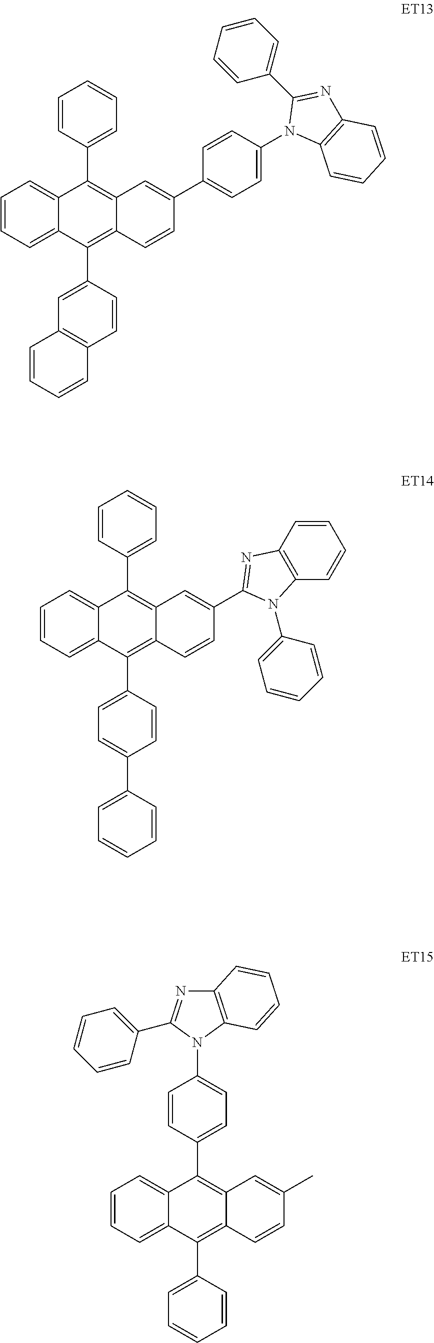 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

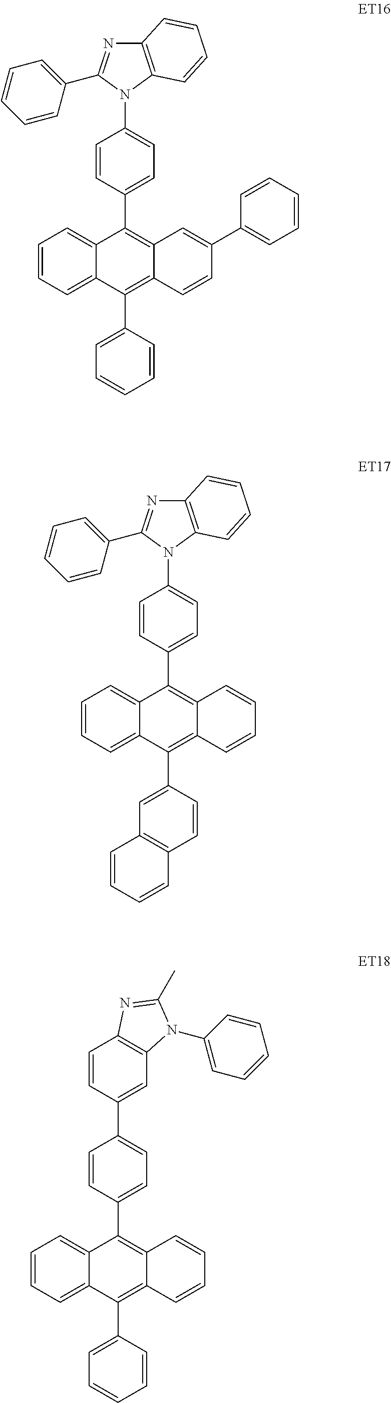 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

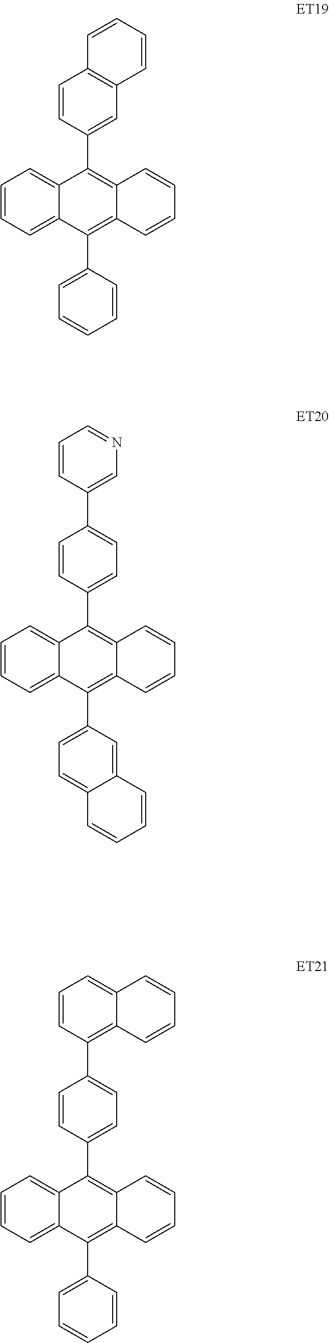

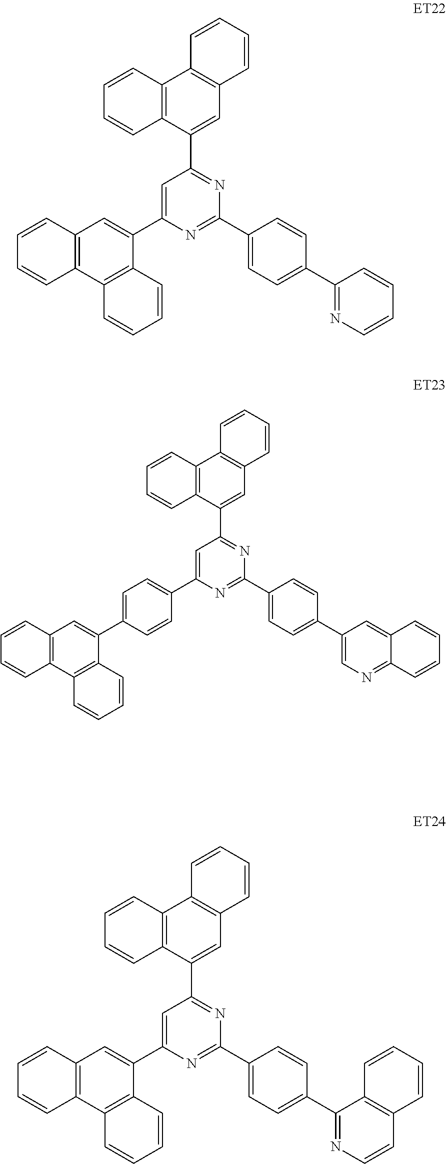 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

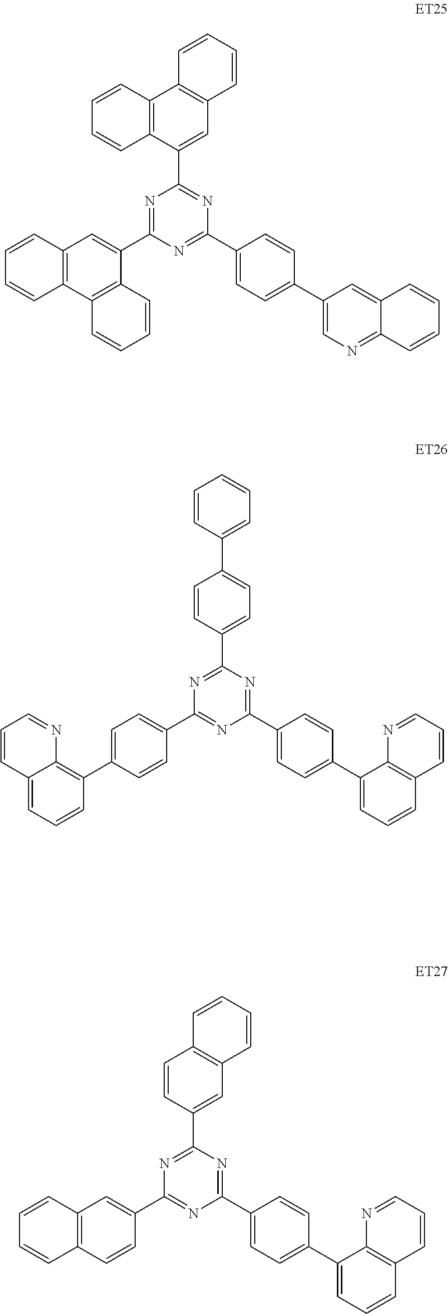 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

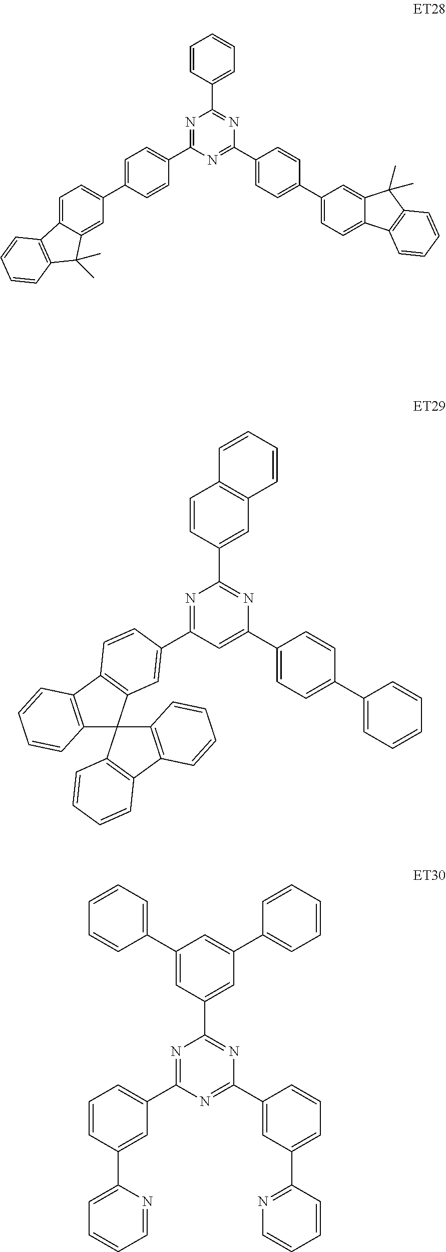 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

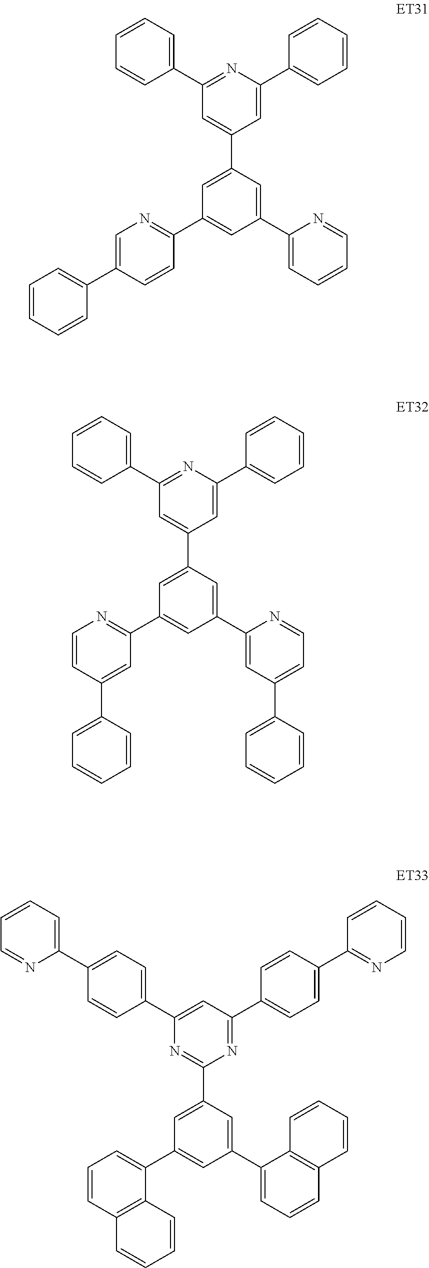 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

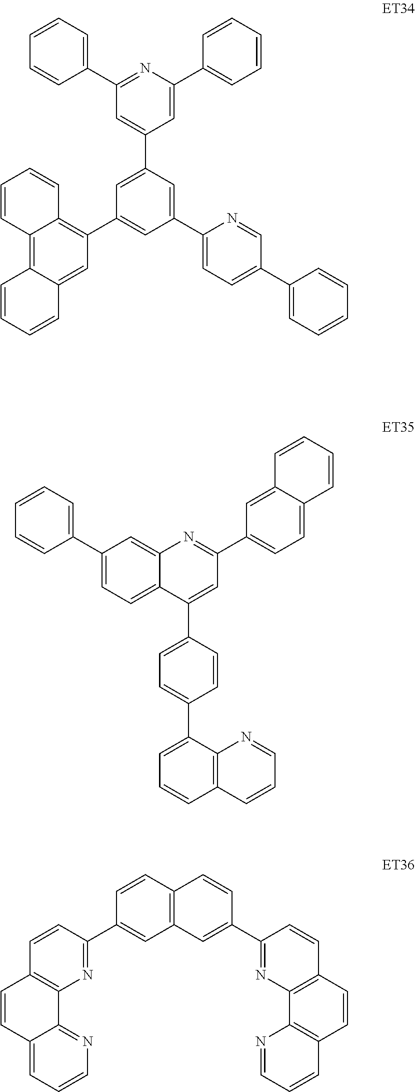 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

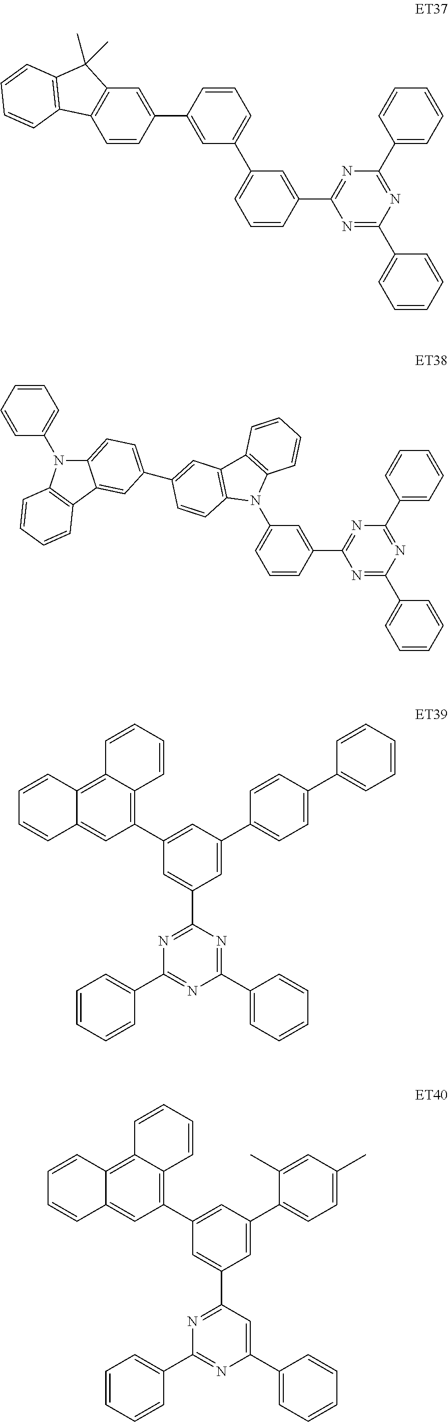 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

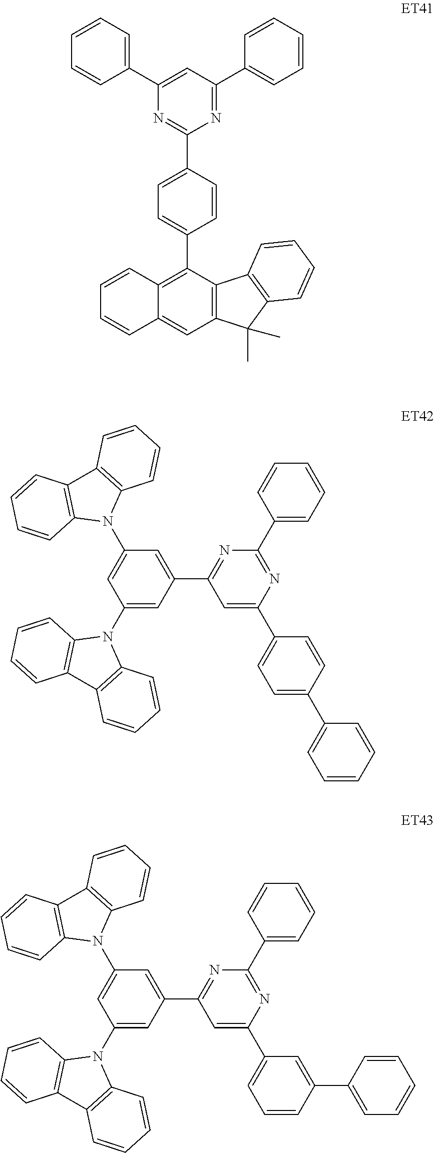 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

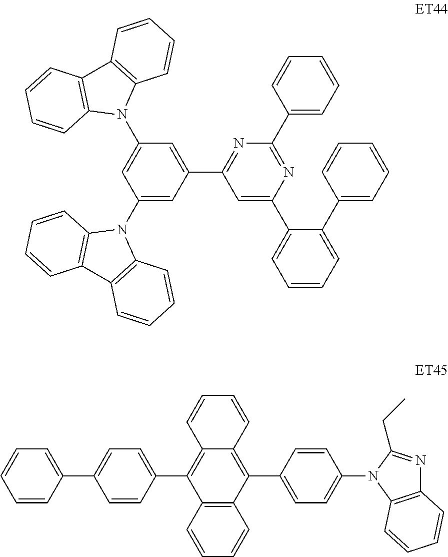 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

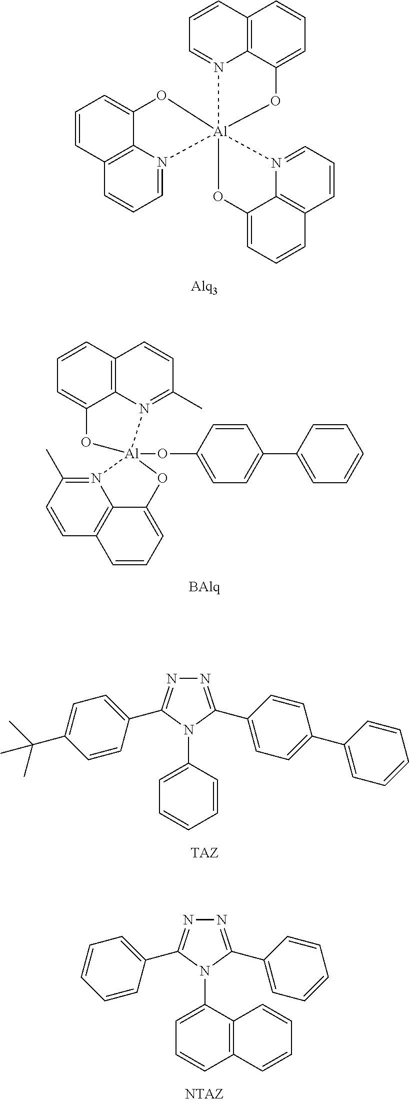

In an embodiment, a thickness of the electron transport region may be in a range of about 100 Å to about 5,000 Å, for example, about 160 Å to about 4,000 Å. In an embodiment in which the electron transport region includes a hole blocking layer, an electron transport layer, or any combination thereof, the thickness of the hole blocking layer or the electron transport layer may be in a range of about 20 Å to about 1,000 Å, for example, about 30 Å to about 300 Å. A thickness of the electron transport layer may be in the range of about 100 Å to about 1,000 Å, for example, about 150 Å to about 500 Å. In an embodiment in which the thicknesses of the hole blocking layer and/or the electron transport layer are within these ranges, satisfactory electron transporting characteristics may be obtained without a substantial increase in driving voltage.

The electron transport region (for example, the electron transport layer in the electron transport region) may further include, in addition to the materials described above, a metal-containing material.

For example, in an embodiment the electron transport layer may include ZnMgOₓ, ZnOₓ, Cs₂CO₃, TiOₓ, WOₓ, SnOₓ, ZnS, or any combination thereof, in which each x may independently represent a number in a range of about 0.1 to about 3.

The metal-containing material may include an alkali metal complex, an alkaline earth metal complex, or any combination thereof. In an embodiment, the metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. In an embodiment, a ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

According to one or more embodiments, the metal-containing material may include a Li complex. In an embodiment, the Li complex may include, for example, Compound ET-D1 (LiQ) or ET-D2:

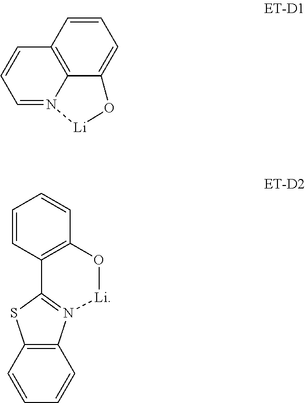

The electron transport region may include an electron injection layer that facilitates the injection of electrons from the second electrode 150. The electron injection layer may directly contact the second electrode 150.

The electron injection layer may have: i) a single-layered structure consisting of a single layer consisting of a single material, ii) a single-layered structure consisting of a single layer consisting of a plurality of different materials, or iii) a multi-layered structure including a plurality of layers including different materials from each other.

In an embodiment, the electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

In an embodiment, the alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

In an embodiment, the alkali metal-containing compound, the alkaline earth metal-containing compound, and the rare earth metal-containing compound may be oxides, halides (for example, fluorides, chlorides, bromides, or iodides), or tellurides of the alkali metal, the alkaline earth metal, and the rare earth metal, or any combination thereof.

In an embodiment, the alkali metal-containing compound may include: alkali metal oxides, such as Li₂O, Cs₂O, or K₂O; alkali metal halides, such as LiF, NaF, CsF, KF, LiI, NaI, CsI, or KI; or any combination thereof. The alkaline earth metal-containing compound may include an alkaline earth metal compound, such as BaO, SrO, CaO, BaₓSr₁₋ₓO in which x is a real number satisfying the condition of 0<x<1, BaₓCa₁₋ₓO in which x is a real number satisfying the condition of 0<x<1, or the like. In an embodiment, the rare earth metal-containing compound may include YbF₃, ScF₃, Sc₂O₃, Y₂O₃, Ce₂O₃, GdF₃, TbF₃, YbI₃, ScI₃, TbI₃, or any combination thereof. According to one or more embodiments, the rare earth metal-containing compound may include lanthanide metal telluride. Examples of the lanthanide metal telluride are LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

In an embodiment, the alkali metal complex, the alkaline earth-metal complex, and the rare earth metal complex may include i) one of ions of the alkali metal, the alkaline earth metal, and the rare earth metal and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. According to one or more embodiments, the electron injection layer may further include an organic material (e.g., a compound represented by Formula 601).

According to one or more embodiments, the electron injection layer may consist of i) an alkali metal-containing compound (e.g., alkali metal halide), ii) a) an alkali metal-containing compound (e.g., alkali metal halide); and b) an alkali metal, an alkaline earth metal, a rare earth metal, or any combination thereof. For example, the electron injection layer may be a KI:Yb co-deposited layer, an RbI:Yb co-deposited layer, or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

In an embodiment, the electron injection layer may include ZnMgOₓ, ZnOₓ, Cs₂CO₃, TiOₓ, WOₓ, SnOₓ, ZnS, 4,7-diphenyl-1,10-phenanthroline (BPhen), 2,2′,2″-(1,3,5-benzinetriyl)-tris(1-phenyl-1-H-benzimidazole) (TPBi), Alq₃, 2,9-dimethyl-4,7-diphenyl-1,10-phenanthroline (BCP), or any combination thereof in which x is a number in a range of about 0.1 to about 3.

In an embodiment, a thickness of the electron injection layer may be in a range of about 1 Å to about 100 Å, and, for example, about 3 Å to about 90 Å. When the thickness of the electron injection layer is within the ranges described above, satisfactory electron injection characteristics may be obtained without a substantial increase in driving voltage.

### [Second Electrode 150]

The second electrode 150 may be located on (e.g., disposed directly above) the interlayer 130 having a structure as described above. The second electrode 150 may face the first electrode 110 (e.g., in a thickness direction of the light-emitting device 100). In an embodiment, the second electrode 150 may be a cathode, which is an electron injection electrode, and as the material for the second electrode 150, a metal, an alloy, an electrically conductive compound, or any combination thereof, each having a low-work function, may be used.

In an embodiment, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transreflective electrode, or a reflective electrode.

The second electrode 150 may have a single-layered structure or a multi-layered structure including a plurality of layers.

### [Capping Layer]

In an embodiment, a first capping layer may be located outside the first electrode 110, and/or a second capping layer may be located outside the second electrode 150. In an embodiment, the light-emitting device 100 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

Light generated in an emission layer of the interlayer 130 of the light-emitting device 100 may be extracted towards the outside through the first electrode 110 which is a transreflective electrode or a transmissive electrode, and the first capping layer. Light generated in an emission layer of the interlayer 130 of the light-emitting device 100 may be extracted towards the outside through the second electrode 150 which is a transreflective electrode or a transmissive electrode, and the second capping layer.

The first capping layer and the second capping layer may increase external emission efficiency according to the principle of constructive interference. Accordingly, the optical extraction efficiency of the light-emitting device 100 may be increased, thus increasing the luminescence efficiency of the light-emitting device 100.

Each of the first capping layer and the second capping layer may include a material having a refractive index greater than or equal to about 1.6 (at 589 nm).

The first capping layer and the second capping layer may each independently be an organic capping layer including an organic material, an inorganic capping layer including an inorganic material, or an organic-inorganic composite capping layer including an organic material and an inorganic material.

In an embodiment, at least one of the first capping layer and the second capping layer may each independently include carbocyclic compounds, heterocyclic compounds, amine group-containing compounds, porphine derivatives, phthalocyanine derivatives, naphthalocyanine derivatives, alkali metal complexes, alkaline earth metal complexes, or any combination thereof. In some embodiments, the carbocyclic compound, the heterocyclic compound, and the amine group-containing compound may be substituted with a substituent including O, N, S, Se, Si, F, Cl, Br, I, or any combination thereof.

According to one or more embodiments, at least one of the first capping layer and the second capping layer may each independently include an amine group-containing compound.

According to one or more embodiments, at least one of the first capping layer and the second capping layer may each independently include a compound represented by Formula 201, a compound represented by Formula 202, or any combination thereof.

According to one or more embodiments, at least one of the first capping layer and the second capping layer may each independently be one of Compounds CP1 to CP6, β-NPB, or any compound:

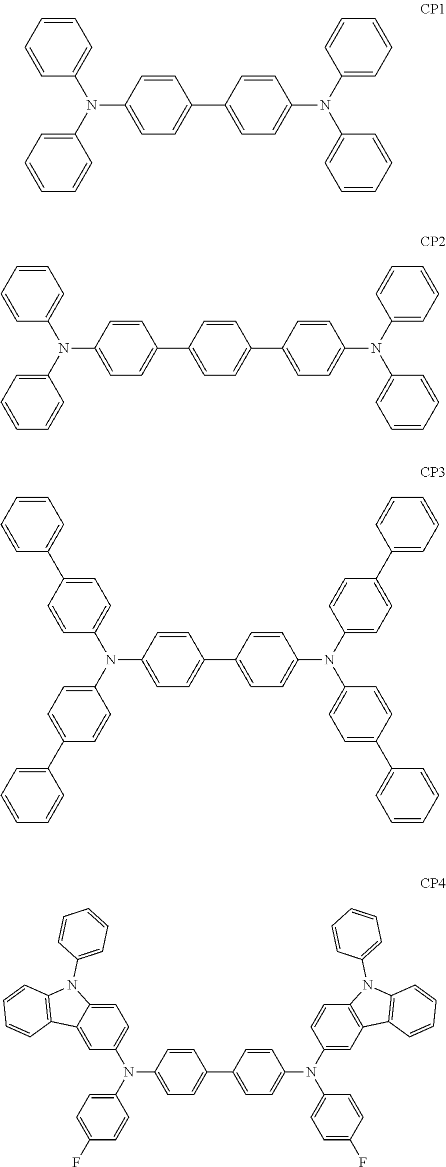 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

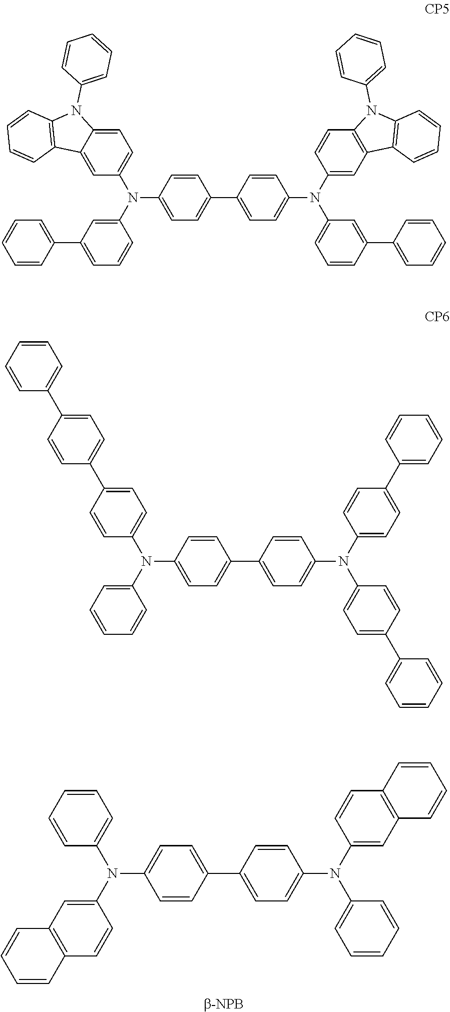 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Electronic Apparatus]

The light-emitting device may be included in various electronic apparatuses. For example, the electronic apparatus including the light-emitting device may be a light-emitting apparatus, an authentication apparatus, or the like.

In an embodiment, the electronic apparatus (e.g., a light-emitting apparatus) may further include, in addition to the light-emitting device, i) a color filter, ii) a color conversion layer, or iii) a color filter and a color conversion layer. The color filter and/or the color conversion layer may be located in at least one direction in which light emitted from the light-emitting device travels. For example, the light emitted from the light-emitting device may be blue light or white light. For details on the light-emitting device, related description provided above may be referred to.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be located among the subpixel areas to define each of the subpixel areas.

The color filter may further include a plurality of color filter areas and light-shielding patterns located among the color filter areas, and the color conversion layer may further include a plurality of color conversion areas and light-shielding patterns located among the color conversion areas.

The plurality of color filter areas (e.g., the plurality of color conversion areas) may include a first area emitting first color light, a second area emitting second color light, and/or a third area emitting third color light. The first color light, the second color light, and/or the third color light may have different maximum emission wavelengths from one another. According to one or more embodiments, the first color light may be red light, the second color light may be green light, and the third color light may be blue light. According to one or more embodiments, the plurality of color filter areas (or the plurality of color conversion areas) may include quantum dots. For example, in an embodiment the first area may include a red quantum dot, the second area may include a green quantum dot, and the third area may not include a quantum dot. For details on the quantum dot, related descriptions provided herein may be referred to. The first area, the second area, and/or the third area may each include a scatter (e.g., a scattering particle).

The regions comprising quantum dots may be formed using a composition including a quantum dot-containing complex according to an embodiment.

According to one or more embodiments, the light-emitting device may emit first light, the first area may absorb the first light to emit first-1 color light, the second area may absorb the first light to emit second-1 color light, and the third area may absorb the first light to emit third-1 color light. In this regard, the first-first color light, the second-first color light, and the third-first color light may have different maximum emission wavelengths from each other. For example, in an embodiment the first light may be blue light, the first-first color light may be red light, the second-first color light may be green light, and the third-first color light may be blue light.

The electronic apparatus may further include a thin-film transistor, in addition to the light-emitting device as described above. The thin-film transistor may include a source electrode, a drain electrode, and an activation layer in which any one of the source electrode and the drain electrode may be electrically connected to any one of the first electrode and the second electrode of the light-emitting device.

The thin-film transistor may further include a gate electrode, a gate insulating film, or the like.

In an embodiment, the activation layer may include crystalline silicon, amorphous silicon, an organic semiconductor, an oxide semiconductor, or the like.

The electronic apparatus may further include a sealing portion for sealing the light-emitting device. The sealing portion may be located between the color filter and/or the color conversion layer and the light-emitting device. The sealing portion allows light from the light-emitting device to be extracted to the outside, and simultaneously prevents ambient air and moisture from penetrating into the light-emitting device. The sealing portion may be a sealing substrate including a transparent glass substrate or a plastic substrate. In an embodiment, the sealing portion may be a thin-film encapsulation layer including at least one layer of an organic layer and/or an inorganic layer. In an embodiment in which the sealing portion is a thin film encapsulation layer, the electronic apparatus may be flexible.

Various functional layers may be additionally located on the sealing portion, in addition to the color filter and/or the color conversion layer, according to the use of the electronic apparatus. Examples of the functional layers may include a touch screen layer, a polarizing layer, and the like. The touch screen layer may be a pressure-sensitive touch screen layer, a capacitive touch screen layer, or an infrared touch screen layer.

The authentication apparatus may be, for example, a biometric authentication apparatus that authenticates an individual by using biometric information of a living body (e.g., fingertips, pupils, etc.).

The authentication apparatus may further include, in addition to the light-emitting device as described above, a biometric information collector.

In an embodiment, the electronic apparatus may be applied to various displays, light sources, lighting, personal computers (e.g., a mobile personal computer), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

### [Electronic Equipment]

The light-emitting device may be included in various electronic equipment.

For example, in an embodiment the consumer product may be one of a flat panel display, a curved display, a computer monitor, a medical monitor, a TV, a billboard, indoor or outdoor illuminations and/or signal light, a head-up display, a fully or partially transparent display, a flexible display, a rollable display, a foldable display, a stretchable display, a laser printer, a phone, a cell phone, a smartphone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including multiple displays tiled together, a theater screen, a stadium screen, a phototherapy device, and a signboard. However, embodiments of the present disclosure are not necessarily limited thereto and the electronic apparatus and electronic equipment that includes the light-emitting device may include various other small-sized, medium-sized or large-sized electronic apparatuses or electronic equipment.

The light-emitting device may have excellent effects in terms of luminescence efficiency long lifespan, and thus the electronic equipment including the light-emitting device may have characteristics, such as high luminance, high resolution, and low power consumption.

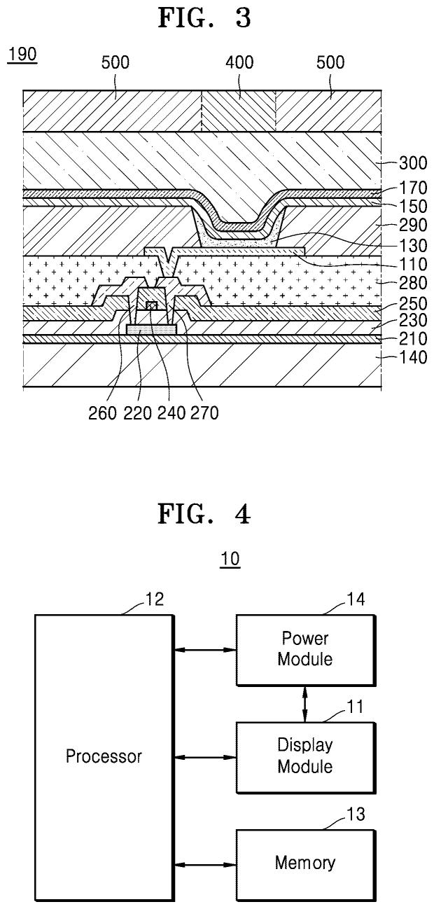

### [Description of FIGS. 2 and 3]

FIG. 2 is a cross-sectional view of an electronic apparatus 180 according to an embodiment of the disclosure.

The electronic apparatus 180 of FIG. 2 includes a substrate 140, a thin-film transistor (TFT), a light-emitting device, and an encapsulation portion 300 that seals the light-emitting device.

In an embodiment, the substrate 140 may be a flexible substrate, a glass substrate, or a metal substrate. A buffer layer 210 may be located on the substrate 140. The buffer layer 210 may prevent penetration of impurities through the substrate 140 and may provide a flat surface on the substrate 140.

A TFT may be located on (e.g., disposed directly thereon) the buffer layer 210. The TFT may include an activation layer 220, a gate electrode 240, a source electrode 260, and a drain electrode 270.

In an embodiment, the activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be located on (e.g., disposed directly thereon) the activation layer 220, and the gate electrode 240 may be located on (e.g., disposed directly thereon) the gate insulating film 230.

An interlayer insulating film 250 may be located on (e.g., disposed directly thereon) the gate electrode 240. The interlayer insulating film 250 may be positioned between (e.g., directly between) the gate electrode 240 and the source electrode 260 to insulate the gate electrode 240 from the source electrode 260 and between (e.g., directly between) the gate electrode 240 and the drain electrode 270 to insulate the gate electrode 240 from the drain electrode 270.

The source electrode 260 and the drain electrode 270 may be located on (e.g., disposed directly thereon) the interlayer insulating film 250. The interlayer insulating film 250 and the gate insulating film 230 may be formed to expose the source region and the drain region of the activation layer 220, and the source electrode 260 and the drain electrode 270 may be located in contact with the exposed portions of the source region and the drain region of the activation layer 220.

The TFT is electrically connected to a light-emitting device to drive the light-emitting device, and is covered and protected by a passivation layer 280. The passivation layer 280 may include an inorganic insulating film, an organic insulating film, or any combination thereof. A light-emitting device is provided on (e.g., disposed directly thereon) the passivation layer 280. In an embodiment, the light-emitting device may include a first electrode 110, an interlayer 130, and a second electrode 150.

In an embodiment, the first electrode 110 may be located on (e.g., disposed directly thereon) the passivation layer 280. The passivation layer 280 may be located to expose a portion of the drain electrode 270, not fully covering the drain electrode 270, and the first electrode 110 may be located to be connected to the exposed portion of the drain electrode 270.

A pixel defining layer 290 including an insulating material may be located on (e.g., disposed directly thereon) the first electrode 110. The pixel defining layer 290 may expose a certain region of the first electrode 110, and an interlayer 130 may be formed in the exposed region of the first electrode 110. For example, in an embodiment, the pixel defining layer 290 may be disposed directly on lateral ends of the first electrode 110 and may expose a central portion of the first electrode 110. In an embodiment, the pixel defining layer 290 may be a polyimide or polyacrylic organic film. In an embodiment, at least some layers of the interlayer 130 may extend beyond the upper portion of the pixel defining layer 290 to be located in the form of a common layer.

In an embodiment, the second electrode 150 may be located on (e.g., disposed directly thereon) the interlayer 130, and a capping layer 170 may be additionally formed on (e.g., disposed directly thereon) the second electrode 150. The capping layer 170 may be formed to cover the second electrode 150.

The encapsulation portion 300 may be located on (e.g., disposed directly thereon) the capping layer 170. The encapsulation portion 300 may be located on a light-emitting device to protect the light-emitting device from moisture or oxygen. In an embodiment, the encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, or the like), an epoxy-based resin (e.g., aliphatic glycidyl ether (AGE), or the like), or any combination thereof; or any combination of the inorganic films and the organic films.

FIG. 3 is a cross-sectional view of an electronic apparatus 190 according to an embodiment of the disclosure.

The electronic apparatus 190 of FIG. 3 is the same as the electronic apparatus of FIG. 2, except that a light-shielding pattern 500 and a functional region 400 are further arranged on (e.g., disposed directly thereon) the encapsulation portion 300. The functional region 400 may be i) a color filter area, ii) a color conversion area, or iii) a combination of the color filter area and the color conversion area. According to one or more embodiments, the light-emitting device included in the light-emitting apparatus of FIG. 4 may be a tandem light-emitting device.

### [Description of FIG. 4]

A light-emitting device according to an embodiment may be applied to various electronic apparatus. An electronic apparatus according to an embodiment may include the light-emitting device described above, and may further include a module or device having additional functions in addition to the light-emitting device.

FIG. 4 is a block diagram of an electronic apparatus 10 according to an embodiment. Referring to FIG. 4, an electronic apparatus 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information for the operation of the processor 12 or display module 11 may be stored in the memory 13. When the processor 12 executes an application (e.g., an application program) stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic apparatus 10.

At least one of the components of the electronic apparatus 10 may be included in the light-emitting device according to such embodiments described above. Additionally, some of the individual modules functionally included within a module may be included within a light-emitting device, while others may be provided separately from the light-emitting device. For example, the light-emitting device may include the display module 11, and the processor 12, the memory 13 and the power module 14 may be provided in the form of other devices within the electronic apparatus 10 other than the light-emitting device.

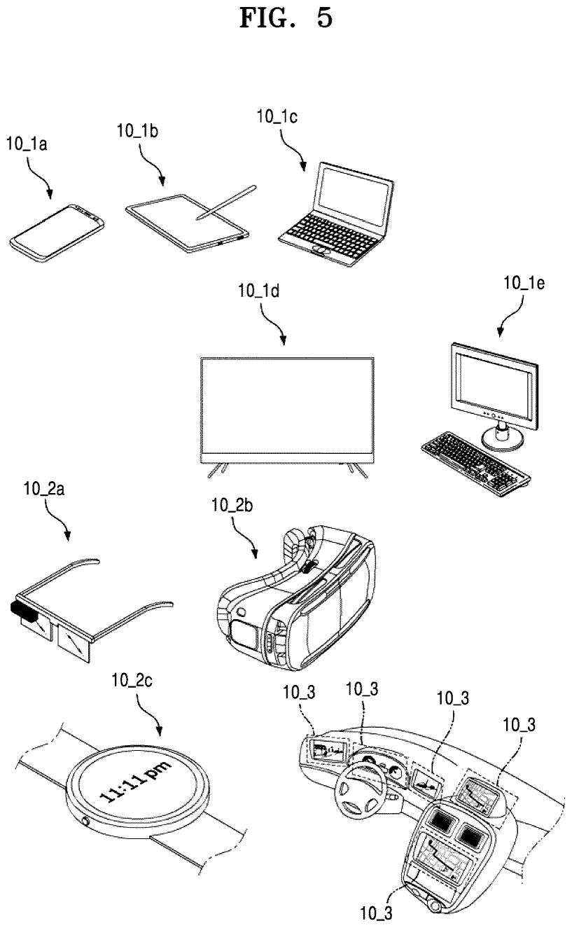

### [Description of FIG. 5]

FIG. 5 shows schematic diagrams of an electronic apparatus according to various embodiments.

Referring to FIG. 5, various electronic apparatus to which the light-emitting device according to embodiments is applied may include not only image display electronic apparatus such as a smart phone 10_1a, a tablet PC 10_1b, a laptop 10_1c, a TV 10_1d, and a desk monitor 10_1e, but also wearable electronic apparatus including display modules such as smart glasses 10_2a, a head mounted display 10_2b, and a smart watch 10_2c, and vehicle electronic apparatus 10_3 including display modules such as a dashboard, center fascia, a center information display (CID) arranged on a car instrument panel, and a room mirror display.

### [Manufacturing Method]

In an embodiment, the layers constituting the hole transport region, the emission layer, and the layers constituting the electron transport region may be formed in a certain region by using various methods such as vacuum deposition, spin coating, casting, Langmuir-Blodgett (LB) deposition, ink-jet printing, laser-printing, laser-induced thermal imaging, and the like.

In an embodiment, the color filter area, color conversion area, etc. may be formed in a predetermined area using a spin coating method, a casting method, an inkjet printing method, etc.

When the layers constituting the emission layer and the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

When the layers constituting the emission layer and the electron transport region are formed by spin coating, the spin coating may be performed at a coating speed in a range of about 2,000 rpm to about 5,000 rpm and at a heat treatment temperature of in a range of about 80° C. to about 200° C. by taking into account a material to be included in a layer to be formed and the structure of a layer to be formed.

A composition according to an embodiment may be used in a solution process such as spin coating or inkjet printing.

### Definition of Terms

The term “C₃-C₆₀ carbocyclic group” as used herein refers to a cyclic group consisting of carbon only as a ring-forming atom and having three to sixty carbon atoms, and the term “C₁-C₆₀ heterocyclic group” as used herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. According to one or more embodiments, the number of ring-forming atoms of the C₁-C₆₀ heterocyclic group may be in a range of 3 to 61.

The “cyclic group” as used herein may include the C₃-C₆₀ carbocyclic group, and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

According to one or more embodiments, the C₃-C₆₀ carbocyclic group may be i) group T1 or ii) a condensed cyclic group in which two or more groups T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group);
the C₁-C₆₀ heterocyclic group may be i) group T2, ii) a condensed cyclic group in which two or more groups T2 are condensed with each other, or iii) a condensed cyclic group in which at least one group T2 and at least one group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.);
the π electron-rich C₃-C₆₀ cyclic group may be i) group T1, ii) a condensed cyclic group in which two or more groups T1 are condensed with each other, iii) group T3, iv) a condensed cyclic group in which two or more groups T3 are condensed with each other, or v) a condensed cyclic group in which at least one group T3 and at least one group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.);
the π electron-deficient nitrogen-containing C₁-C₆₀ cyclic group may be i) group T4, ii) a condensed cyclic group in which two or more groups T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.);
the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group;
the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group;
the group T3 may be a furan group, a thiophene group, a 1H-pyrrole group, a silole group, or a borole group; and
the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as used herein refer to a group condensed to any cyclic group, a monovalent group, or a polyvalent group (e.g., a divalent group, a trivalent group, a tetravalent group, etc.) according to the structure of a formula for which the corresponding term is used. According to one or more embodiments, “a benzene group” may be a benzo group, a phenyl group, a phenylene group, or the like, which may be easily understand by one of ordinary skill in the art according to the structure of a formula including the “benzene group.”

In an embodiment, examples of a monovalent C₃-C₆₀ carbocyclic group and a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has one to sixty carbon atoms, and specific examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof are an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof include an ethynyl group, a propynyl group, and the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ in which A₁₀₁ is the C₁-C₆₀ alkyl group, and examples thereof are a methoxy group, an ethoxy group, an isopropyloxy group, and the like.

The term “C₃-C₁₀ cycloalkyl group” as used herein refers to a monovalent saturated hydrocarbon cyclic group having 3 to 10 carbon atoms, and examples thereof include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom, as ring-forming atoms, and specific examples are a 1,2,3,4-oxatriazolidinyl group, a tetrahydrofuranyl group, and a tetrahydrothienyl group. The term “C₁-C₁₀ heterocycloalkylene group” as used herein refers to a divalent group having the same structure as the C₁-C₁₀ heterocycloalkyl group.

The term C₃-C₁₀ cycloalkenyl group used herein refers to a monovalent cyclic group that has three to ten carbon atoms and at least one carbon-carbon double bond in the ring thereof and no aromaticity, and specific examples thereof are a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. In an embodiment in which the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group (e.g., having 8 to 60 carbon atoms) having two or more rings condensed to each other, only carbon atoms as ring-forming atoms, and no aromaticity in its entire molecular structure. Examples of the monovalent non-aromatic condensed polycyclic group are an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (e.g., having 1 to 60 carbon atoms) having two or more rings condensed to each other, further including, in addition to a carbon atom, at least one heteroatom as a ring-forming atom, and having no aromaticity in its entire molecular structure. Examples of the monovalent non-aromatic condensed heteropolycyclic group include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having the same structure as the monovalent non-aromatic condensed heteropolycyclic group described above.

The term “C₆-C₆₀ aryloxy group” as used herein indicates —OA₁₀₂ in which A₁₀₂ is the C₆-C₆₀ aryl group, and the term “C₆-C₆₀ arylthio group” as used herein indicates —SA₁₀₃ in which A₁₀₃ is the C₆-C₆₀ aryl group.

The term “C₇-C₆₀ aryl alkyl group” used herein refers to -A₁₀₄A₁₀₅ in which A₁₀₄ may be a C₁-C₅₄ alkylene group, and A₁₀₅ may be a C₆-C₅₉ aryl group, and the term C₂-C₆₀ heteroaryl alkyl group” used herein refers to -A₁₀₆A₁₀₇ in which A₁₀₆ may be a C₁-C₅₉ alkylene group, and A₁₀₇ may be a C₁-C₅₉ heteroaryl group.

The term “R₁₀ₐ” as used herein refers to:
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, cyano group, a C₁-C₆₀ alkyl group, a C₁-C₆₀ alkoxy group, a phenyl group, a biphenyl group, or any combination thereof.

The term “heteroatom” as used herein refers to any atom other than a carbon atom. Examples of the heteroatom are O, S, N, P, Si, B, Ge, Se, and any combinations thereof.

The term “transition metal” as used herein may include Hf, Ta, W, Re, Os, Ir, Pt, Au, or the like.

The term “Ph” as used herein refers to a phenyl group, the term “Me” as used herein refers to a methyl group, the term “Et” as used herein refers to an ethyl group, the term “tert-Bu” or “Bu^{t}” as used herein refers to a tert-butyl group, and the term “OMe” as used herein refers to a methoxy group.

The term “biphenyl group” as used herein refers to “a phenyl group substituted with a phenyl group.” For example, the “biphenyl group” is a substituted phenyl group having a C₆-C₆₀ aryl group as a substituent.

The term “terphenyl group” as used herein refers to “a phenyl group substituted with a biphenyl group”. For example, the “terphenyl group” is a substituted phenyl group having, as a substituent, a C₆-C₆₀ aryl group substituted with a C₆-C₆₀ aryl group.

The number of carbon atoms in the substituent definition is an example and the number of carbon atoms may vary. In an embodiment, the maximum carbon number of 60 in the C₁-C₆₀ alkyl group is an example, and the definition of the alkyl group is equally applied to a C₁-C₂₀ alkyl group. The same applies to other cases.

Any hydrogen in the compound structures described herein may optionally be substituted with deuterium.

* and *′ as used herein, unless defined otherwise, each refer to a binding site to a neighboring atom in a corresponding formula.

Hereinafter, a compound and light-emitting device according to embodiments of the present disclosure will be described in detail with reference to Examples.

### EXAMPLES

### Manufacture of Light-Emitting Device

### Example 1

A 15 Ω/cm² (800 Å) Ag/ITO glass substrate was cut into a size of 50 mm×50 mm×0.5 mm, ultrasonically cleaned using isopropyl alcohol and pure water for 5 minutes each, irradiated with ultraviolet light for 15 minutes, cleaned by exposure to ozone, and mounted on a vacuum deposition apparatus.

On the ITO substrate, Al₂O₃ (thickness: 0.5 nm)/quantum dot emission layer (red InP quantum dot/thickness: 15 nm)/electron transport layer (ZnMgO/thickness: 50 nm)/Al electrode (thickness: 130 nm) were sequentially formed to fabricate a light-emitting device.

The electron transport layer and the Al electrode were formed by a vapor deposition method.

The layer consisting of an insulating material, Al₂O₃, the quantum dot emission layer and the electron transport layer were formed by an inkjet coating method. The layer consisting of the insulating material, the quantum dot emission layer and the electron transport layer were subjected to a Vacuum Chamber Dry (VCD) process at 10-3 Torr after thin film formation, followed by a bake process at 100° C. for 10 minutes.

### Example 2

A light-emitting device was fabricated in a manner equal to that in Example 1, except that the thickness of the layer consisting of Al₂O₃ is 1 nm.

### Example 3

A light-emitting device was fabricated in a manner equal to that in Example 1, except that the thickness of the layer consisting of Al₂O₃ is 5 nm.

### Example 4

A light-emitting device was fabricated in a manner equal to that in Example 1, except that the thickness of the layer consisting of HfO₂ (instead of Al₂O₃) is 0.5 nm.

### Comparative Example 1

A light-emitting device was fabricated in a manner equal to that in Example 1, except that hole injection layer (PEDOT:PSS=1:1 wt %)(thickness: 45 nm) and hole transport layer (TFB: poly[(9,9-dioctylfluorenyl-2,7-diyl)-co-(4,4′-(N-(4-sec-butylphenyl) diphenylamine)])(thickness: 30 nm) were sequentially formed instead of the layer consisting of Al₂O₃ on the ITO substrate.

### Comparative Example 2

A light-emitting device was fabricated in a manner equal to that in Example 1, except that the thickness of the layer consisting of Al₂O₃ is 10 nm.

### Comparative Example 3

A light-emitting device was fabricated in a manner equal to that in Example 1, except that the thickness of the layer consisting of Al₂O₃ is 23 nm.

The light-emitting devices fabricated in the Examples and the Comparative Examples were characterized and the results are shown in Table 1. The driving voltage and luminance of the light-emitting device were measured using a source meter Keithley SMU 236 and a luminance meter PR650.

TABLE 1

| | Thickness(nm) | Voltage(V, @5 mA/cm²) |
|---|---|---|
| Example 1 | [Al₂O₃] 0.5 | 1.4 |
| Example 2 | [Al₂O₃] 1 | 3.6 |
| Example 3 | [Al₂O₃] 5 | 4.9 |
| Comparative | [Al₂O₃] 10 | 12.3 |
| Example 2 | | |
| Comparative | [Al₂O₃] 23 | >20 |
| Example 3 | | |

From the results of Table 1, it may be seen that light-emitting devices of the Examples had lower driving voltage than the light-emitting devices of the Comparative Example.

Lifespan according to luminance was measured by T₅₀, where T₅₀ represents the time required for the luminance to reach 50% of the initial luminance. The results are shown in Table 2.

TABLE 2

| | | | T₅₀ (h) with |
|---|---|---|---|
| | | | L₀ converted |
| | | | to 1,000 cd/m² |
| | | | [Acceleration |
| | T₅₀ (h) | | factor n 1.8] |
| Example 1 [Al₂O₃] | 20 | (L₀ = 13,000 cd/m²), | up to 2,000 |
| Example 4 [HfO₂] | 178 | (L₀ = 6,400 cd/m²) | up to 5,000 |
| Comparative | 30 | (L₀ = 1,400 cd/m²) | up to 55 |

Example 1
[PEDOT:PSS/TFB]

From the results of T₅₀ (h) with L₀ converted to 1,000 cd/m² in Table 2, it can be seen that the devices of Example have a better life span than the devices of Comparative Example.

According to the one or more embodiments, a light-emitting device may have excellent lifespan.

It should be understood that embodiments described herein should be considered in a descriptive sense only and not for purposes of limitation. Descriptions of features or aspects within each embodiment should typically be considered as available for other similar features or aspects in other embodiments. While one or more non-limiting embodiments have been described with reference to the figures, it will be understood by those of ordinary skill in the art that various changes in form and details may be made therein without departing from the spirit and scope of the present disclosure.

What is claimed is:

1. A light-emitting device comprising:
a first electrode;
a second electrode facing the first electrode; and
an interlayer arranged between the first electrode and the second electrode and comprising an emission layer,
wherein the emission layer comprises a quantum dot, and
a charge modulation layer is arranged between the first electrode and the emission layer.

2. The light-emitting device of claim 1, wherein:
the first electrode is an anode;
the second electrode is a cathode; and
the interlayer further comprises
an electron transport region comprising a hole blocking layer, an electron transport layer, an electron injection layer, or any combination thereof.

3. The light-emitting device of claim 2, wherein:
the electron transport region is arranged between the second electrode and the emission layer; and
the electron transport region comprises the electron transport layer and/or the electron injection layer,
wherein the electron transport layer and/or the electron injection layer each independently comprises an inorganic compound, an organic compound or any combination thereof.

4. The light-emitting device of claim 3, wherein:
the electron transport layer and the electron injection layer each independently comprise ZnMgOₓ, ZnOₓ, Cs₂CO₃, TiOₓ, WOₓ, SnOₓ, ZnS, 4,7-diphenyl-1,10-phenanthroline (BPhen), 2,2′,2″-(1,3,5-benzinetriyl)-tris(1-phenyl-1-H-benzimidazole) (TPBi), Alq₃, 2,9-dimethyl-4,7-diphenyl-1,10-phenanthroline (BCP), or any combination thereof,
wherein each x independently represents a number in a range of about 0.1 to about 3.

5. The light-emitting device of claim 1, wherein:
the charge modulation layer comprises an inorganic insulating material, an organic insulating material, or any combination thereof.

6. The light-emitting device of claim 5, wherein:
the inorganic insulating material comprises: an aluminum oxide; an aluminum nitride; a titanium nitride; an alkali metal halide; a silicon oxide; a silicon nitride; a silicon oxynitride; a hafnium oxide; a zirconium oxide; or an oxide of a combination of 2 or more of an aluminum, a silicon, a hafnium and a zirconium.

7. The light-emitting device of claim 5, wherein:
the inorganic insulating material comprises Al₂O₃, SiOₓ, SiNₓ, SiOₓN_{y}, HfO₂, ZrO₂, HfSiO₄, HfAlO, AlNₓ, TiNₓ, LiF, or any combination thereof,
wherein x is a number in a range of about 0.1 to about 3, and y is a number in a range of about 0.1 to about 3.

8. The light-emitting device of claim 5, wherein:
the organic insulating material comprises poly(methyl methacrylate) (PMMA), polyvinyl alcohol (PVA), or any combination thereof.

9. The light-emitting device of claim 1, wherein:
the first electrode is an anode;
the second electrode is a cathode; and
a thickness of the charge modulation layer is less than or equal to about 5 nm.

10. The light-emitting device of claim 1, wherein:
the first electrode and/or the second electrode is a transmissive electrode.

11. The light-emitting device of claim 10, wherein:
the transmissive electrode have a single-layer structure or a multilayer structure each comprising a metal oxide or a metal.

12. The light-emitting device of claim 11, wherein:
the metal oxide comprises an indium tin oxide (ITO), an indium zinc oxide (IZO), a tin oxide doped with a fluorine (FTO), a molybdenum oxide (MoOₓ), a vanadium oxide (VOₓ), a nickel oxide (NiOₓ), a tin oxide (SnO₂), a zinc oxide (ZnO), or any combination thereof,
wherein each x independently represents a number in a range of about 0.1 to about 3.

13. The light-emitting device of claim 11, wherein:
the metal comprises a magnesium (Mg), a silver (Ag), a gold (Au), an aluminum (Al), an aluminum-lithium (Al—Li), a calcium (Ca), a magnesium-indium (Mg—In), a magnesium-silver (Mg—Ag), or any combination thereof.

14. The light-emitting device of claim 1, wherein:
the quantum dot has a core-shell structure, the core-shell structure comprising:
a core comprising a semiconductor compound; and
a shell comprising an oxide of a metal, a metalloid, or a non-metal, a semiconductor compound, or a combination thereof.

15. The light-emitting device of claim 14, wherein:
the semiconductor compound comprises a Group II-VI semiconductor compound, a Group III-V semiconductor compound, a Group III-VI semiconductor compound, a Group I-III-VI semiconductor compound, a Group IV-VI semiconductor compound, a Group IV element or compound, or a combination thereof; and
the oxide of a metal, a metalloid, or a non-metal each independently comprises SiO₂, Al₂O₃, TiO₂, ZnO, MnO, Mn₂₀₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, or a combination thereof.

16. The light-emitting device of claim 14, wherein:
the semiconductor compound comprises CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, InAlZnP, GaS, GaSe, Ga₂Se₃, GaTe, InS, InSe, In₂S₃, In₂Se₃, InTe, InGaS₃, InGaSe₃, AgInS, AgInS₂, CuInS, CuInS₂, CuGaO₂, AgGaO₂, AgAlO₂, AgInGaS, AgInGaS₂, CuInGaS₂, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, SiGe or any combination thereof.

17. The light-emitting device of claim 14, wherein:
the semiconductor compound included in the shell comprises CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or a combination thereof.

18. An electronic apparatus, comprising:
a processor;
a memory having stored application programs for execution by the processor;
a light-emitting device comprising:
a first electrode;
a second electrode facing the first electrode; and
an interlayer arranged directly between the first electrode and the second electrode and comprising an emission layer, the interlayer does not include any of a hole injection layer and a hole transport layer,
wherein the emission layer comprises a quantum dot, and
a charge modulation layer is arranged between the first electrode and the emission layer.

19. The electronic apparatus of claim 18, wherein:
the light-emitting device includes a display module; and
the electronic apparatus includes a power module including a power supply module supplying power to the electronic apparatus.

20. The electronic apparatus of claim 18, wherein
the electronic apparatus is one of a smartphone, a tablet PC, a laptop, a TV, a desk monitor, smart glasses, a head mounted display, a smart watch, an automobile instrument panel, a center fascia, a center information display (CID) arranged on a dashboard of an automobile, and a room mirror display.
